(19) United States
(12) Patent Application Publication
(10) Pub. No.: US 2018/0315890 A1
(43) Pub. Date: Nov. 1, 2018

(54) SEMICONDUCTOR LAYERED BODY, LIGHT EMITTING DEVICE, AND METHOD FOR MANUFACTURING LIGHT EMITTING DEVICE

(71) Applicants: Sumitomo Electric Industries, Ltd., Osaka-shi, Osaka (JP); RIKEN, Wako-shi, Saitama (JP)

(72) Inventors: Susumu YOSHIMOTO, Itami-shi, Hyogo (JP); Masaki UENO, Itami-shi, Hyogo (JP); Katsushi AKITA, Itami-shi, Hyogo (JP); Yoshiyuki YAMAMOTO, Itami-shi, Hyogo (JP); Hideki HIRAYAMA, Wako-shi, Saitama (JP)

(73) Assignees: Sumitomo Electric Industries, Ltd., Osaka-shi, Osaka (JP); RIKEN, Wako-shi, Saitama (JP)

(21) Appl. No.: 15/771,730

(22) PCT Filed: Oct. 28, 2016
(86) PCT No.: PCT/JP2016/082114

§ 371 Date: Apr. 27, 2018

(30) Foreign Application Priority Data
Nov. 2, 2015 (JP) 2015-216005

(51) Int. Cl. H01L 33/32; H01L 33/06; H01L 33/36; H01L 33/00

(52) U.S. Cl. CPC H01L 33/32; H01L 33/0075; H01L 33/36; H01L 33/06

(57) ABSTRACT

A semiconductor layered body includes: a plurality of protrusions having first main surfaces along a reference plane and protruding from the reference plane; and a first semiconductor layer disposed at a side of the plurality of protrusions opposite to the first main surfaces so as to connect the plurality of protrusions to one another. Each of the protrusions is composed of a group III nitride that has a dislocation density of less than or equal to 1×10⁸ cm⁻³, that is expressed by a composition formula of AlₓGa₁₋ₓN, and that satisfies 0≤x<1. The first semiconductor layer is composed of a group III nitride that has a dislocation density of less than or equal to 1×10⁹ cm⁻³, that is expressed by a composition formula of Al_{y}Ga_{1-y}N, and that satisfies 0<y≤1.

### TECHNICAL FIELD

The present invention relates to a semiconductor layered body, a light emitting device, and a method for manufacturing the light emitting device. The present application claims a priority based on Japanese Patent Application No. 2015-216005 filed on Nov. 2, 2015, the entire content of which is incorporated herein by reference.

### BACKGROUND ART

A semiconductor layered body including a semiconductor layer composed of a group III nitride can be used for production of a light emitting device. Specifically, for example, a light emitting device for emitting ultraviolet light can be obtained by providing an AlN layer, an n type AlGaN layer, a quantum well structure, and a p type AlGaN layer in this order on a sapphire substrate and forming an appropriate electrode (for example, see Non-Patent Document 1).

### CITATION LIST

### Non Patent Document

NPD 1: M. Kneissl, et al., “Advances in group III-nitride-based deep UV light-emitting diode technology”, Semicond.Sci.Technol.26(2011)014036

### SUMMARY OF INVENTION

A semiconductor layered body according to the present invention includes: a plurality of protrusions having first main surfaces along a reference plane and protruding from the reference plane; and a first semiconductor layer disposed at a side of the plurality of protrusions opposite to the first main surfaces so as to connect the plurality of protrusions to one another. Each of the protrusions is composed of a group III nitride that has a dislocation density of less than or equal to 1×10⁸ cm⁻³, that is expressed by a composition formula of AlₓGa₁₋ₓN, and that satisfies 0≤x<1. The first semiconductor layer is composed of a group III nitride that has a dislocation density of less than or equal to 1×10⁹ cm⁻³, that is expressed by a composition formula of Al_{y}Ga_{1-y}N, and that satisfies 0<y≤1.

A method for manufacturing a light emitting device according to the present invention includes: preparing a semiconductor layered body; and forming an electrode on the semiconductor layered body. The preparing of the semiconductor layered body includes: forming a plurality of protrusions having first main surfaces along a reference plane and protruding from the reference plane; and forming a first semiconductor layer at a side of the plurality of protrusions opposite to the first main surfaces so as to connect the plurality of protrusions to one another. Each of the protrusions is composed of a group III nitride that has a dislocation density of less than or equal to 1×10⁸ cm⁻³, that is expressed by a composition formula of AlₓGa₁₋ₓN, and that satisfies 0≤x<1. The first semiconductor layer is composed of a group III nitride that has a dislocation density of less than or equal to 1×10⁹ cm⁻³, that is expressed by a composition formula of Al_{y}Ga_{1-y}N, and that satisfies 0<y≤1.

### BRIEF DESCRIPTION OF DRAWINGS

FIG. 1 is a schematic cross sectional view showing a structure of a semiconductor layered body.

FIG. 2 is a schematic plan view showing the structure of the semiconductor layered body.

FIG. 3 is a schematic plan view showing a structure of a semiconductor layered body in a first modification.

FIG. 4 is a schematic plan view showing a structure of a semiconductor layered body in a second modification.

FIG. 5 is a schematic plan view showing a structure of a semiconductor layered body in a third modification.

FIG. 6 is a schematic cross sectional view showing a structure of a quantum well structure equipped semiconductor layered body.

FIG. 7 is a schematic cross sectional view showing a structure of a light emitting device in the first embodiment.

FIG. 8 is a flowchart schematically showing methods for manufacturing the semiconductor layered body and the light emitting device in the first embodiment.

FIG. 9 is a schematic cross sectional view for illustrating the methods for manufacturing the semiconductor layered body and the light emitting device.

FIG. 10 is a schematic cross sectional view for illustrating the methods for manufacturing the semiconductor layered body and the light emitting device.

FIG. 11 is a schematic cross sectional view showing a structure of a base layered body.

FIG. 12 is a schematic cross sectional view for illustrating the methods for manufacturing the semiconductor layered body and the light emitting device.

FIG. 13 is a schematic cross sectional view for illustrating the methods for manufacturing the semiconductor layered body and the light emitting device.

FIG. 14 is a schematic cross sectional view showing a structure of a light emitting device manufactured by a manufacturing method of a second embodiment.

FIG. 15 is a flowchart schematically showing methods for manufacturing a semiconductor layered body and the light emitting device in the second embodiment.

FIG. 16 is a schematic cross sectional view showing a semiconductor layered body of a comparative example.

FIG. 17 is a schematic cross sectional view showing a light emitting device of a comparative example.

### DESCRIPTION OF EMBODIMENTS

### Problems to be Solved by the Present Disclosure

In the structure disclosed in Non-Patent Document 1, it is difficult to sufficiently reduce the dislocation density of the AlN layer formed on the sapphire substrate. This results in low crystallinity of the semiconductor layer including the quantum well structure formed on the AlN layer. As a result, it is difficult to provide the light emitting device with a sufficient light emitting property, disadvantageously. In view of this, it is one of objects to provide: a semiconductor layered body allowing for an improved light emitting property of a light emitting device; a light emitting device having an improved light emitting property; and a method for manufacturing such a light emitting device.

### Advantageous Effect of the Present Disclosure

According to the semiconductor layered body and the method for manufacturing the light emitting device, the light emitting property of the light emitting device can be improved.

### Description of Embodiments of the Invention of the Present Application

First, embodiments of the invention of the present application are listed and described. A semiconductor layered body according to the present application includes: a plurality of protrusions having first main surfaces along a reference plane and protruding from the reference plane; and a first semiconductor layer disposed at a side of the plurality of protrusions opposite to the first main surfaces so as to connect the plurality of protrusions to one another. Each of the protrusions is composed of a group III nitride that has a dislocation density of less than or equal to 1×10⁸ cm⁻³, that is expressed by a composition formula of AlₓGa₁₋ₓN, and that satisfies 0≤x<1. The first semiconductor layer is composed of a group III nitride that has a dislocation density of less than or equal to 1×10⁹ cm⁻³, that is expressed by a composition formula of Al_{y}Ga_{1-y}N, and that satisfies 0<y≤1.

In the semiconductor layered body of the present application, the first semiconductor layer is disposed on the plurality of protrusions protruding from the reference plane so as to connect the plurality of protrusions to one another. By employing such a structure, a region not in contact with the protrusions is formed on the main surface of the first semiconductor layer at the protrusion side so as to correspond to a portion between adjacent protrusions (groove between the adjacent protrusions) when viewed in a plan view. Accordingly, a stress resulting from a difference in lattice constant between each protrusion and the first semiconductor layer is released in the region. Accordingly, the crystallinity of the first semiconductor layer is suppressed from being deteriorated due to the difference in lattice constant between the protrusion and the first semiconductor layer. The dislocation density of the protrusion is reduced to less than or equal to 1×10⁸ cm⁻³, thereby obtaining the first semiconductor layer having a dislocation density of less than or equal to 1×10⁹ cm⁻³. As a result, when a semiconductor layer including a quantum well structure is formed on the first semiconductor layer, a quantum well structure excellent in crystallinity is obtained. The quantum well structure excellent in crystallinity contributes to improvement in light emitting property. Thus, according to the semiconductor layered body of the present application, there can be provided a semiconductor layered body allowing for an improved light emitting property of a light emitting device.

The semiconductor layered body may further include a supporting body having a supporting main surface overlapping with the reference plane. The plurality of protrusions may be formed on the supporting main surface. This facilitates formation of the plurality of protrusions protruding from the reference plane.

In the semiconductor layered body, the first semiconductor layer may have a dislocation density of less than or equal to 1×10⁸ cm⁻³. Accordingly, there can be obtained a quantum well structure having more excellent crystallinity.

In the semiconductor layered body, when viewed in a plan view, an area ratio of a region overlapping with the protrusions in the first semiconductor layer may be more than or equal to 30% and less than or equal to 90%. When the area ratio of the region overlapping with the protrusions is less than 30%, it becomes difficult to form the first semiconductor layer so as to connect the plurality of protrusions to one another. On the other hand, when the area ratio of the region overlapping with the protrusions is more than 90%, the stress resulting from the difference in lattice constant between each protrusion and the first semiconductor layer is not sufficiently released. When the area ratio of the region overlapping with the protrusions is set at more than or equal to 30% and less than or equal to 90%, it is possible to facilitate formation of the first semiconductor layer to connect the plurality of protrusions to one another while sufficiently releasing the stress resulting from the difference in lattice constant between each protrusion and the first semiconductor layer.

In the semiconductor layered body, in the first semiconductor layer, a half width of an X-ray rocking curve of a (0002) plane, which is a symmetric plane, may be less than or equal to 800 arcsec and a half width of an X-ray rocking curve of a (10-12) plane, which is an asymmetric plane, may be less than or equal to 1500 arcsec. In this way, a quantum well structure having more excellent crystallinity can be obtained.

The semiconductor layered body may further include a second semiconductor layer disposed on a main surface of the first semiconductor layer opposite to the protrusions, the second semiconductor layer including a quantum well structure. In this way, there can be obtained a semiconductor layered body including a quantum well structure having excellent crystallinity.

In the semiconductor layered body, each of the protrusions may have a thickness of less than or equal to 10 μm. Even though a thickness of more than 10 μm is not secured, the stress resulting from the difference in lattice constant between the protrusion and the semiconductor layer can be sufficiently released. Moreover, the thickness of the protrusion is preferably more than or equal to 10 nm. Accordingly, the stress can be released more securely. Furthermore, the thickness of the protrusion is more preferably more than or equal to 100 nm. Accordingly, the stress can be released much more securely.

A light emitting device according to the present application includes: the above-described semiconductor layered body; and an electrode formed on the semiconductor layered body. According to the light emitting device of the present application, the light emitting property can be improved because the light emitting device includes the semiconductor layered body with which a quantum well structure serving as a light emitting layer having excellent crystallinity can be obtained.

The light emitting device may be configured to emit ultraviolet light. A quantum well structure serving as a light emitting layer that emits ultraviolet light can be formed on the first semiconductor layer composed of a group III nitride that is expressed by the composition formula of Al_{y}Ga_{1-y}N and that satisfies 0<y≤1.

A method for manufacturing a light emitting device according to the present application includes: preparing a semiconductor layered body; and forming an electrode on the semiconductor layered body. The preparing of the semiconductor layered body includes: forming a plurality of protrusions having first main surfaces along a reference plane and protruding from the reference plane; and forming a first semiconductor layer at a side of the plurality of protrusions opposite to the first main surfaces so as to connect the plurality of protrusions to one another. Each of the protrusions is composed of a group III nitride that has a dislocation density of less than or equal to 1×10⁸ cm⁻³, that is expressed by a composition formula of AlₓGa₁₋ₓN, and that satisfies 0≤x<1. The first semiconductor layer is composed of a group III nitride that has a dislocation density of less than or equal to 1×10⁹ cm⁻³, that is expressed by a composition formula of Al_{y}Ga_{1-y}N, and that satisfies 0<y≤1.

In the preparing of the semiconductor layered body of the method for manufacturing the light emitting device in the present application, the first semiconductor layer is formed on the plurality of protrusions protruding from the reference plane so as to connect the plurality of protrusions to one another. By employing such a procedure, a region not in contact with the protrusions is formed on the main surface of the first semiconductor layer at the protrusion side so as to correspond to a portion between adjacent protrusions (groove between the adjacent protrusions) when viewed in a plan view. Accordingly, a stress resulting from a difference in lattice constant between each protrusion and the first semiconductor layer is released in the region. Accordingly, the crystallinity of the first semiconductor layer is suppressed from being deteriorated due to the difference in lattice constant between the protrusion and the first semiconductor layer. The dislocation density of the protrusion is reduced to less than or equal to 1×10⁸ cm⁻³, thereby obtaining the first semiconductor layer having a dislocation density of less than or equal to 1×10⁹ cm⁻³. As a result, when a semiconductor layer including a quantum well structure is formed on the first semiconductor layer, a quantum well structure excellent in crystallinity is obtained. The quantum well structure excellent in crystallinity contributes to improvement in light emitting property. By forming an electrode on such a semiconductor layered body, a light emitting device having an excellent light emitting property can be manufactured. Thus, according to the method for manufacturing the light emitting device in the present application, the light emitting property of the light emitting device can be improved.

In the method for manufacturing the light emitting device, in the forming of the protrusions, the plurality of protrusions may be formed on a supporting main surface of a supporting body, the supporting main surface overlapping with the reference plane. This facilitates formation of the plurality of protrusions protruding from the reference plane.

In the method for manufacturing the light emitting device, the preparing of the semiconductor layered body may further include forming a second semiconductor layer on a main surface of the first semiconductor layer opposite to the protrusions, the second semiconductor layer including a quantum well structure. In this way, a light emitting device including a quantum well structure serving as a light emitting layer having excellent crystallinity can be manufactured.

In the method for manufacturing the light emitting device, the preparing of the semiconductor layered body may further include removing the protrusions and the first semiconductor layer after the forming of the second semiconductor layer. Also with such a procedure, a light emitting device having an excellent light emitting property can be manufactured.

### Details of Embodiments of the Invention of the Present Application

### First Embodiment

Next, with reference to figures, the following describes a first embodiment, which is one embodiment of a semiconductor layered body and a light emitting device according to the present invention. It should be noted that in the below-mentioned figures, the same or corresponding portions are given the same reference characters and are not described repeatedly.

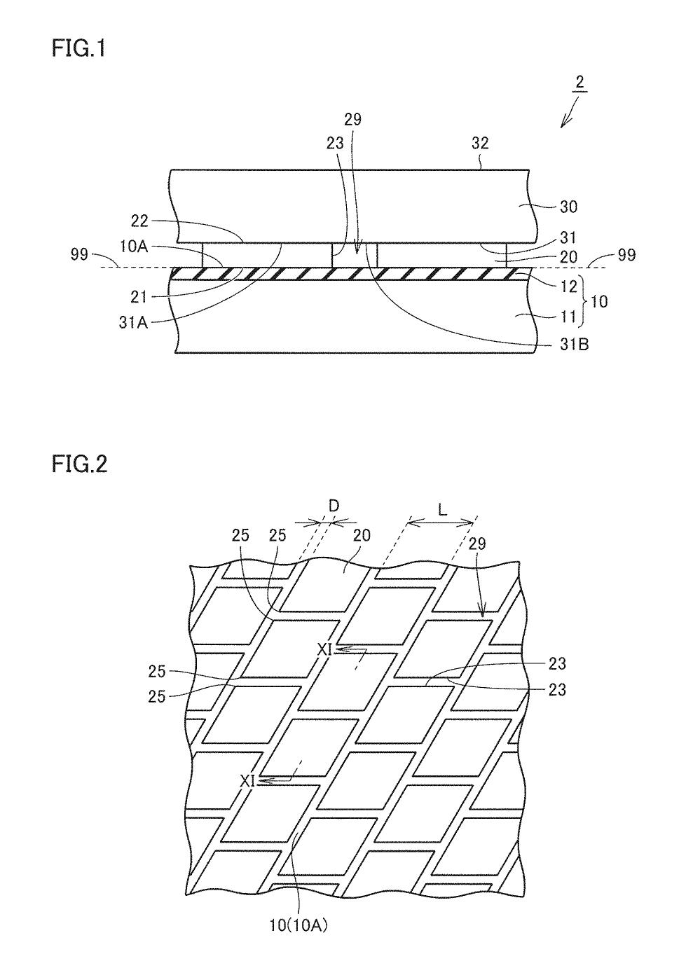

With reference to FIG. 1, a semiconductor layered body 2 in the present embodiment includes a supporting body 10, a plurality of protrusions 20, and a first semiconductor layer 30.

Supporting body 10 includes a base body 11 and a dielectric film 12. Supporting body 10 has a supporting main surface 10A. Base body 11 has a plate-like shape. Base body 11 has a disc-like shape, for example. Base body 11 has a diameter of more than or equal to 50 mm, for example. The diameter of base body 11 may be more than or equal to 100 mm, or may be more than or equal to 150 mm. Base body 11 can be composed of mullite, anorthite, molybdenum, silicon, aluminum nitride, or silicon carbide, for example.

Dielectric film 12 is disposed on and in contact with one main surface of base body 11. Dielectric film 12 may be constituted of a dielectric composed of one or more compounds selected from a group consisting of SiO₂ (silicon dioxide), SiON (silicon oxynitride), SiN (silicon nitride), TiN (titanium nitride), HfO (hafnium oxide), TiO₂ (titanium dioxide), ZrO₂ (zirconium dioxide), Al₂O₃ (aluminum oxide), or Ga₂O₃ (gallium oxide), for example. A main surface of dielectric film 12 opposite to base body 11 is supporting main surface 10A of supporting body 10.

Each of protrusions 20 protrudes from a reference plane 99. Supporting main surface 10A of supporting body 10 overlaps with reference plane 99. That is, a plane including supporting main surface 10A coincides with reference plane 99. Protrusion 20 has a first main surface 21, a second main surface 22, and end surfaces 23. First main surface 21 and second main surface 22 correspond to a {0001} plane of the crystal of protrusion 20, for example. End surface 23 corresponds to a {11-20} plane of the crystal of protrusion 20, for example. All the end surfaces 23 may correspond to the {11-20} plane of the crystal of protrusion 20. First main surface 21 is along reference plane 99. On first main surface 21, protrusion 20 is in contact with supporting main surface 10A of supporting body 10. Respective end surfaces 23 of adjacent protrusions 20 facing each other define a groove portion 29. That is, groove portion 29 is a region (space) interposed between end surfaces 23 of adjacent protrusions 20. Protrusion 20 has a thickness of less than or equal to 10 for example.

Protrusion 20 is constituted of a single crystal having a dislocation density of less than or equal to 1×10⁸ cm⁻³ and composed of aluminum (Al) and nitrogen (N), or aluminum, gallium (Ga) and nitrogen (N). That is, protrusion 20 is composed of a single crystal of a group III nitride expressed by a composition formula of AlₓGa₁₋ₓN and satisfying 0≤x<1. The plurality of protrusions 20 are disposed at an equal interval. Each protrusion 20 has the same plate-like shape. Protrusion 20 has a polygonal shape when viewed in a plan view. That is, protrusion 20 has a polygonal prism shape. The dislocation density thereof can be measured by an etch pit method.

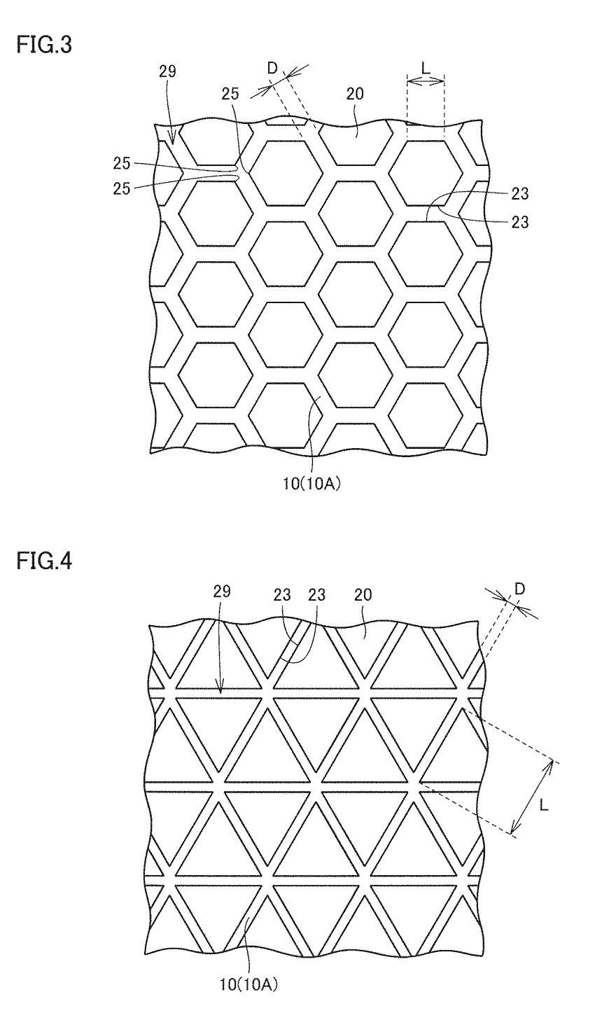

With reference to FIG. 2, in the present embodiment, the planar shapes of protrusions 20 are the same quadrangular shape. The lengths of the sides of the quadrangle are equal to one another. That is, the planar shape of protrusion 20 is in the form of a rhombus. An acute angle of the rhombus is 60°, and an obtuse angle of the rhombus is 120°. Protrusions 20 are disposed to be spread all over supporting main surface 10A of supporting body 10 at an equal interval. When viewed in a plan view, protrusions 20 are disposed at a cycle of less than or equal to 10 Protrusions 20 are disposed such that there are two corner portions 25 of protrusions 20 facing each other. That is, two corner portions 25 are located at a region at which straight lines of groove portion 29 cross each other.

As the planar shape of protrusion 20 in the present embodiment, another shape can be employed. With reference to FIG. 3 to FIG. 5, the following describes modifications of the planar shape of protrusion 20. It should be noted that each of FIG. 2 to FIG. 5 is a plan view showing the supporting main surface 10A side from the first semiconductor layer 30 side with first semiconductor layer 30 in FIG. 1 being removed. With reference to FIG. 3, in a first modification, the planar shape of protrusion 20 is hexagonal. The lengths of the sides of the hexagon are equal to one another. The planar shape of protrusion 20 can be a right hexagon. Protrusions 20 are disposed such that there are three corner portions 25 of protrusions 20 facing one another. That is, three corner portions 25 are located at a region at which straight lines of groove portion 29 cross one another.

With reference to FIG. 4, in a second modification, the planar shape of protrusion 20 is triangular. The lengths of the sides of the triangle are equal to one another. The planar shape of protrusion 20 can be a regular triangle. Protrusions 20 are disposed such that there are six corner portions 25 of protrusions 20 facing one another. That is, six corner portions 25 are located at a region at which straight lines of groove portion 29 cross one another.

With reference to FIG. 5, in a third modification, the planar shape of protrusion 20 is triangular. The lengths of the sides of the triangle are equal to one another. The planar shape of protrusion 20 can be a regular triangle. Protrusions 20 are disposed such that there are three corner portions 25 of protrusions 20 facing one another. That is, three corner portions 25 are located at a region at which straight lines of groove portion 29 cross one another.

With reference to FIG. 1, first semiconductor layer 30 is disposed on second main surface 22 of each of the plurality of protrusions 20 opposite to first main surface 21 so as to connect the plurality of protrusions 20 to one another. First semiconductor layer 30 is composed of a single crystal having a dislocation density of less than or equal to 1×10⁹ cm⁻³. First semiconductor layer 30 is composed of a group III nitride expressed by a composition formula of Al_{y}Ga_{1-y}N and satisfying 0<y≤1 and x<y.

First semiconductor layer 30 has a first main surface 31 and a second main surface 32, which is a main surface opposite to first main surface 31. At first main surface 31, first semiconductor layer 30 is in contact with second main surface 22 of each of protrusions 20. First main surface 31 of first semiconductor layer 30 includes: a contact region 31A in contact with protrusion 20; and a noncontact region 31B not in contact with protrusion 20. When viewed in a plan view, contact region 31A corresponds to a region overlapping with protrusion 20 in first semiconductor layer 30. Noncontact region 31B faces supporting main surface 10A of supporting body 10 with groove portion 29, which is a space, being interposed therebetween.

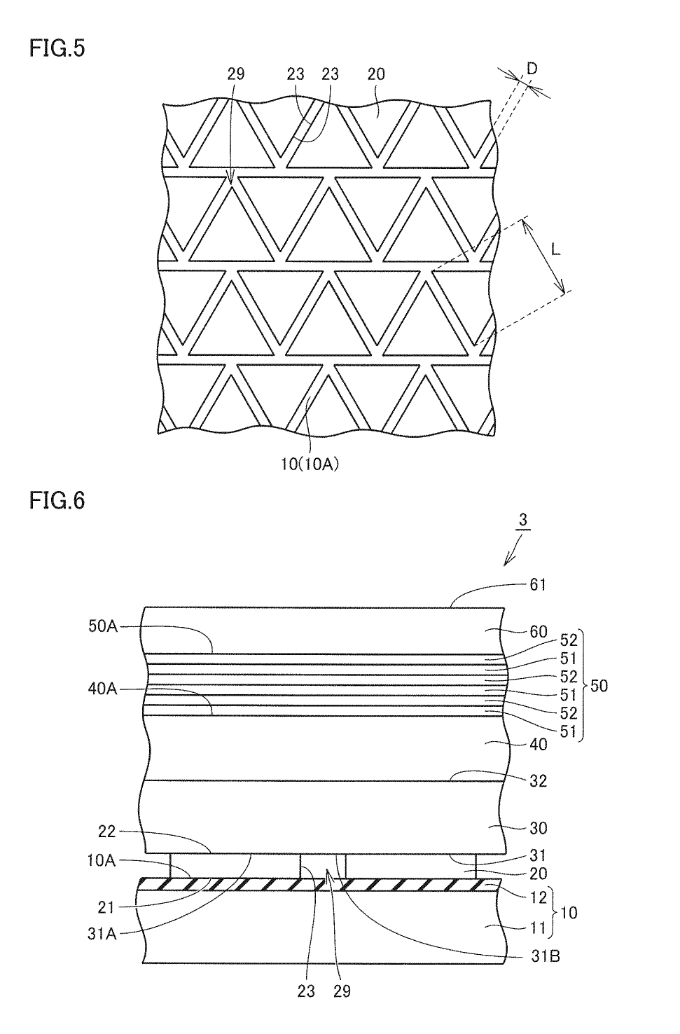

In the semiconductor layered body of the present embodiment, a second semiconductor layer including a quantum well structure may be formed on semiconductor layered body 2 described above. With reference to FIG. 6, a quantum well structure equipped semiconductor layered body 3 serving as the semiconductor layered body in the present embodiment further includes a second semiconductor layer including a quantum well structure 50 and disposed on second main surface 32 of first semiconductor layer 30 opposite to protrusions 20. The second semiconductor layer includes an n type semiconductor layer 40, quantum well structure 50, and a p type semiconductor layer 60.

N type semiconductor layer 40 is a semiconductor layer disposed on and in contact with second main surface 32 of first semiconductor layer 30. N type semiconductor layer 40 is composed of a group III nitride single crystal. Specifically, AlGaN having n type conductivity is employed as a material of n type semiconductor layer 40, for example. Si (silicon) can be employed as an n type impurity included in n type semiconductor layer 40, for example.

Quantum well structure 50 is disposed on and in contact with a first main surface 40A of n type semiconductor layer 40 opposite to its side facing first semiconductor layer 30. Quantum well structure 50 has a structure in which quantum well layers 51, which are composed of a group semiconductor, and barrier layers 52 are alternately layered. Quantum well structure 50 is a light emitting layer that emits ultraviolet light.

P type semiconductor layer 60 is a semiconductor layer disposed on and in contact with main surface 50A of quantum well structure 50 opposite to the side facing n type semiconductor layer 40. P type semiconductor layer 60 is composed of a group III nitride single crystal. Specifically, for example, AlGaN having p type conductivity is employed as a material of p type semiconductor layer 60. As a p type impurity included in p type semiconductor layer 60, Mg (magnesium) can be employed, for example.

It should be noted that in the present embodiment, quantum well structure 50 is a multiple quantum well structure; however, a single quantum well structure can also be employed instead.

In semiconductor layered body 2 and quantum well structure equipped semiconductor layered body 3, first semiconductor layer 30 is disposed on the plurality of protrusions 20 protruding from reference plane 99, so as to connect the plurality of protrusions 20 to one another. By employing such a structure, noncontact region 31B, which is a region not in contact with protrusion 20, is formed at first main surface 31 of first semiconductor layer 30 so as to correspond to groove 29 between adjacent protrusions 20 when viewed in a plan view. Accordingly, a stress resulting from a difference in lattice constant between protrusion 20 and first semiconductor layer 30 is released in noncontact region 31B. Accordingly, the crystallinity of first semiconductor layer 30 is suppressed from being deteriorated due to the difference in lattice constant between protrusion 20 and first semiconductor layer 30. The dislocation density of protrusion 20 is reduced to less than or equal to 1×10⁸ cm⁻³, thereby obtaining first semiconductor layer 30 having a dislocation density of less than or equal to 1×10⁹ cm⁻³. As a result, when the second semiconductor layer including quantum well structure 50 is formed on first semiconductor layer 30, quantum well structure 50 having excellent crystallinity is obtained.

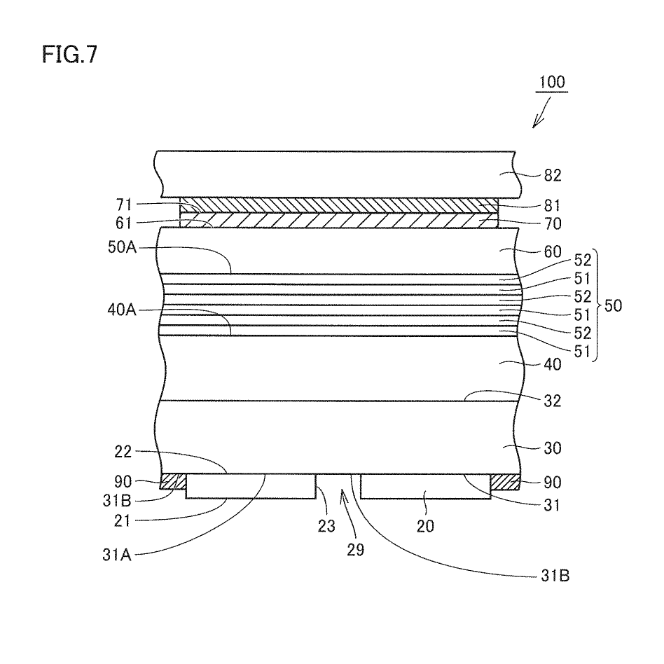

Next, the following describes a light emitting device of the present embodiment. With reference to FIG. 7, a light emitting device 100 in the first embodiment includes: quantum well structure equipped semiconductor layered body 3 from which supporting body 10 has been removed; and electrodes formed on quantum well structure equipped semiconductor layered body 3. More specifically, light emitting device 100 includes: quantum well structure equipped semiconductor layered body 3 from which supporting body 10 has been removed; an n side electrode 90; a p side electrode 70; and a second supporting body 82.

N side electrode 90 is disposed on and in contact with noncontact region 31B of first semiconductor layer 30 of quantum well structure equipped semiconductor layered body 3. N side electrode 90 is composed of a conductor, such as a metal, capable of ohmic contact with first semiconductor layer 30. As the conductor of n side electrode 90, Ti (titanium)/Al (aluminum) can be employed, for example.

P side electrode 70 is disposed on and in contact with a main surface 61 of p type semiconductor layer 60 of quantum well structure equipped semiconductor layered body 3 opposite to quantum well structure 50. P side electrode 70 is composed of a conductor, such as a metal, capable of ohmic contact with p type semiconductor layer 60. As the conductor of p side electrode 70, Ni (nickel)/Au (gold) can be employed, for example.

A second supporting body 82 is joined to p side electrode 70 with a solder layer 81 interposed therebetween. Solder layer 81 can be composed of AuSn, which is an alloy of gold (Au) and tin (Sn), for example. Second supporting body 82 has a plate-like shape. Second supporting body 82 can be composed of CuW (copper tungsten alloy), Cu (copper), or the like, for example.

When voltage is forwardly applied to light emitting device 100, holes are injected from p type semiconductor layer 60 to quantum well structure 50 and electrons are injected from n type semiconductor layer 40 to quantum well structure 50. They are recombined in quantum well structure 50 to emit light. In the present embodiment, because quantum well structure 50 configured as above is employed, ultraviolet light is emitted.

Here, light emitting device 100 of the present embodiment includes quantum well structure 50 as a light emitting layer excellent in crystallinity as described above. Therefore, light emitting device 100 is a light emitting device having an excellent light emitting property (light emitting efficiency) and emitting ultraviolet light.

The dislocation density of first semiconductor layer 30 described above is preferably less than or equal to 1×10⁸ cm⁻³. Accordingly, quantum well structure 50 having more excellent crystallinity can be obtained.

Moreover, when viewed in a plan view, an area ratio of the region overlapping with protrusions 20 in first semiconductor layer 30, i.e., an area ratio of contact region 31A in first main surface 31 of first semiconductor layer 30, is preferably more than or equal to 30% and less than or equal to 90%. This facilitates formation of first semiconductor layer 30 so as to connect the plurality of protrusions 20 to one another while sufficiently releasing the stress resulting from the difference in lattice constant between each protrusion 20 and first semiconductor layer 30.

Furthermore, in first semiconductor layer 30, it is preferable that the half width of an X-ray rocking curve of a (0002) plane, which is a symmetric plane, is less than or equal to 800 arcsec and the half width of an X-ray rocking curve of a (10-12) plane, which is an asymmetric plane, is less than or equal to 1500 arcsec. Accordingly, quantum well structure 50 having more excellent crystallinity can be obtained.

Further, with reference to FIG. 2 to FIG. 5, lengths L of the sides of adjacent protrusions 20 facing each other is preferably 2√3 times or more as large as a distance D between adjacent protrusions 20. This facilitates formation of continuous first semiconductor layer 30 in the lateral direction (direction along second main surface 22 of protrusion 20) when forming first semiconductor layer 30 on protrusions 20.

Further, when viewed in a plan view, the protrusions are preferably disposed at a cycle of less than or equal to 10 μm. Accordingly, the crystallinity of first semiconductor layer 30 can be improved further.

Next, the following describes an overview of methods for manufacturing semiconductor layered body 2, quantum well structure equipped semiconductor layered body 3, and light emitting device 100 in the present embodiment.

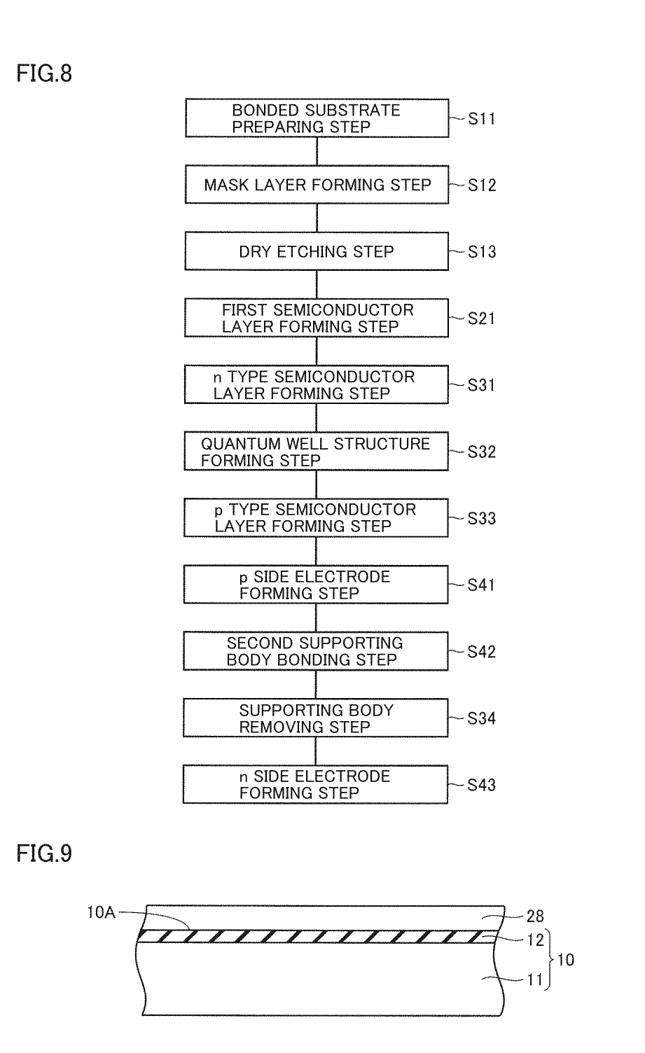

With reference to FIG. 8, a bonded substrate preparing step is first performed as a step (S11) in each of the methods for manufacturing semiconductor layered body 2, quantum well structure equipped semiconductor layered body 3, and light emitting device 100 in the present embodiment. In this step (S11), as shown in FIG. 9, a bonded substrate having a diameter of 2 inches (50.8 mm) is prepared, for example. More specifically, there is prepared a bonded substrate having a structure in which a group III nitride layer 28 is bonded to supporting body 10. Group III nitride layer 28 is composed of a group III nitride that has a dislocation density of less than or equal to 1×10⁸ cm⁻³, that is expressed by a composition formula of AlₓGa₁₋ₓN, and that satisfies 0≤x<1. Supporting body 10 includes base body 11 and dielectric film 12. Dielectric film 12 is a joining layer for joining group III nitride layer 28 to base body 11. The bonded substrate includes: disc-like supporting body 10; and group III nitride layer 28 disposed on supporting main surface 10A of supporting body 10.

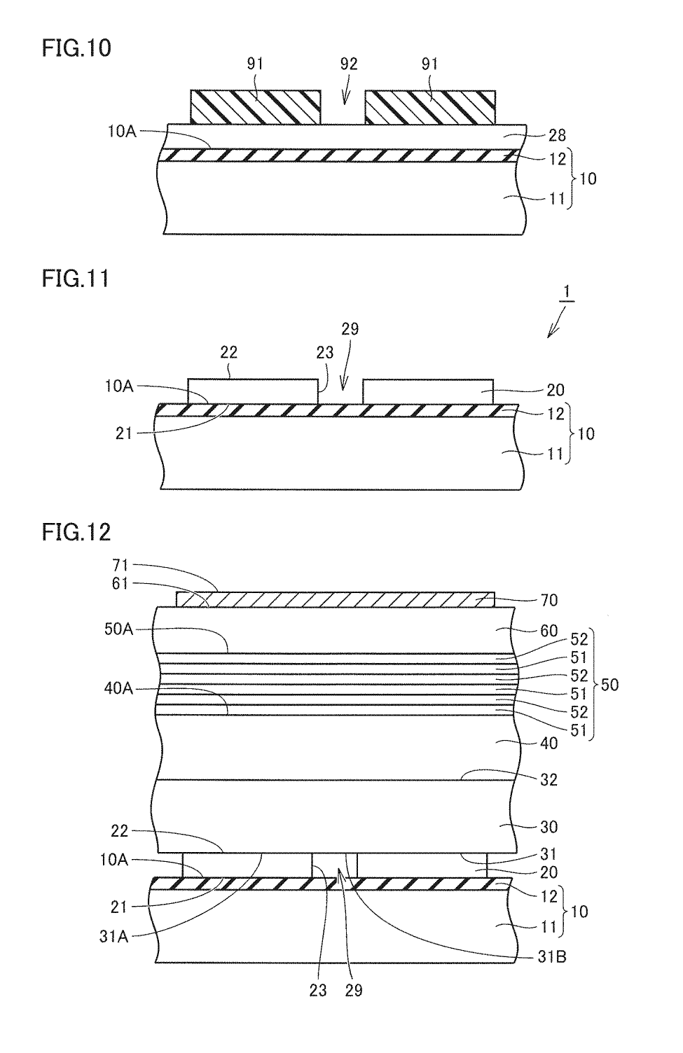

Next, a mask layer forming step is performed as a step (S12). In this step (S12), with reference to FIG. 9 and FIG. 10, a mask layer 91 composed of a resist is formed to cover a region of group III nitride layer 28 to be desired protrusions 20. Mask layer 91 is formed to have an opening 92 in conformity with a region to be groove portion 29. Specifically, for example, a resist layer is formed on group III nitride layer 28 and a photolithography process is employed to form mask layer 91 having opening 92 in conformity with the desired region.

Next, a dry etching step is performed as a step (S13). In this step (S13), with reference to FIG. 10, dry etching is performed using, as a mask, mask layer 91 formed in the step (S12). Accordingly, group III nitride layer 28 in the region corresponding to opening 92 is removed. Then, mask layer 91 is removed, thereby obtaining a base layered body 1 having protrusions 20 protruding from supporting main surface 10A (reference plane) of supporting body 10 as shown in FIG. 11. Base layered body 1 includes: plate-like supporting body 10 having supporting main surface 10A; and the plurality of protrusions 20 each disposed on supporting main surface 10A, each composed of a group III nitride, and each having a dislocation density of less than or equal to 1×10⁸ cm⁻³. Each of protrusions 20 has a plate-like shape. Protrusions 20 are disposed at an equal interval. Each of protrusions 20 has a polygonal planar shape. The plurality of protrusions 20 have the same shape. In the present embodiment, each of protrusions 20 is formed to have end surface 23 corresponding to the {11-20} plane of the crystal of protrusion 20.

Next, a first semiconductor layer forming step is performed as a step (S21). In this step (S21), with reference to FIG. 11 and FIG. 1, first semiconductor layer 30 is formed on protrusions 20 of base layered body 1 obtained in the step (S13). First semiconductor layer 30 can be formed by vapor phase epitaxy, for example. Here, in the steps (S12) and (S13), end surfaces 23 are formed to correspond to the {11-20} plane of the crystal of each of protrusions 20. This facilitates crystal growth in the lateral direction (direction along second main surface 22 of protrusion 20) in the step (S21). As a result, continuous first semiconductor layer 30 is formed readily in the lateral direction (direction along second main surface 22 of protrusion 20). With the above procedure, semiconductor layered body 2 shown in FIG. 1 is obtained.

Next, as steps (S31) to (S33), an n type semiconductor layer forming step, a quantum well structure forming step, and a p type semiconductor layer forming step are performed sequentially. In the step (S31), with reference to FIG. 1 and FIG. 6, an n type semiconductor layer 40 is formed on first semiconductor layer 30 formed in the step (S21). N type semiconductor layer 40 can be formed by vapor phase epitaxy, for example.

In the step (S32), a quantum well structure 50 is formed on n type semiconductor layer 40 formed in the step (S31). Quantum well structure 50 can be formed by vapor phase epitaxy, for example. Quantum well structure 50 can be formed by alternately repeating formation of a quantum well layer 51 and formation of a barrier layer 52.

In the step (S33), p type semiconductor layer 60 is formed on quantum well structure 50 formed in the step (S32). P type semiconductor layer 60 can be formed by vapor phase epitaxy, for example. In the steps (S21), (S31), (S32), and (S33), the respective formations can be performed through the vapor phase epitaxy continuously while changing source material gases. With the above procedure, quantum well structure equipped semiconductor layered body 3 shown in FIG. 6 is obtained.

Next, a p side electrode forming step is performed as a step (S41). In this step (S41), with reference to FIG. 6 and FIG. 12, p side electrode 70 is formed on p type semiconductor layer 60 formed in the step (S33). Specifically, p side electrode 70 composed of Ni/Au is formed on and in contact with main surface 61 of p type semiconductor layer 60 opposite to quantum well structure 50. P side electrode 70 can be formed by a deposition method, for example.

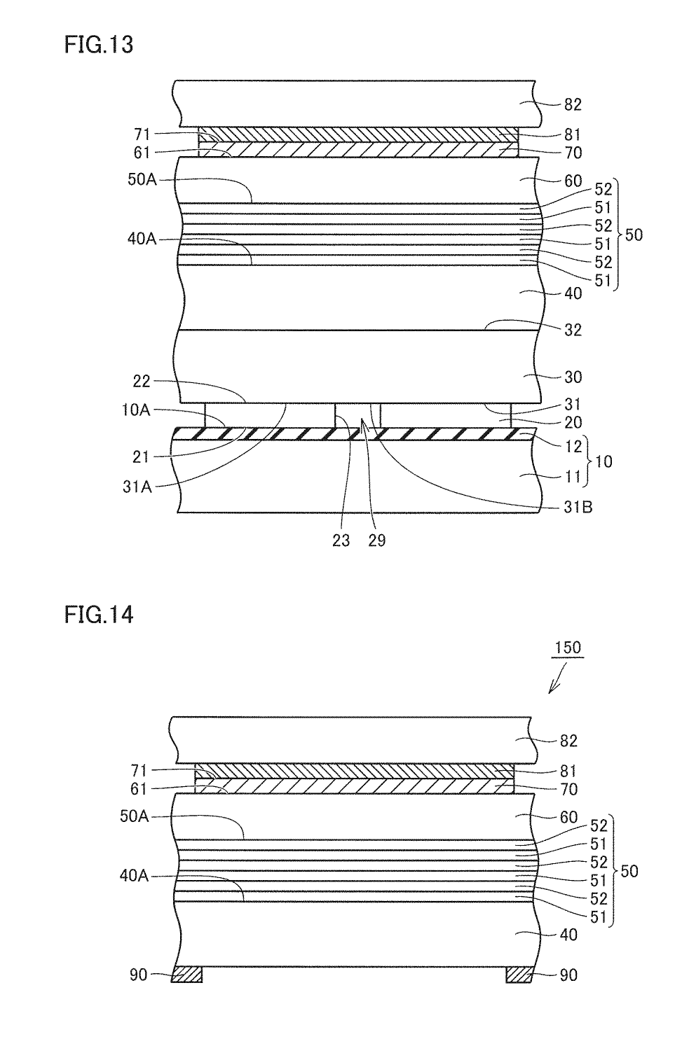

Next, a second supporting body bonding step is performed as a step (S42). In this step (S42), with reference to FIG. 12 and FIG. 13, second supporting body 82 is joined onto main surface 71 of p side electrode 70, formed in the step (S41), opposite to p type semiconductor layer 60 with solder layer 81 interposed therebetween. Specifically, an AuSn solder in a molten state is supplied between p side electrode 70 and second supporting body 82 and is then cooled. Accordingly, p side electrode 70 and second supporting body 82 are bonded to each other.

Next, a supporting body removing step is performed as a step (S34). In this step (S34), with reference to FIG. 13 and FIG. 7, supporting body 10 is removed from the structure shown in FIG. 13. Specifically, for example, dielectric film 12 composed of silicon dioxide is removed by hydrofluoric acid, thereby separating supporting body 10.

Next, an n side electrode forming step is performed as a step (S43). In this step (S43), an n side electrode 90 is formed in contact with noncontact region 31B of first main surface 31 of first semiconductor layer 30, noncontact region 31B being exposed due to the removal of supporting body 10 in the step (S34). N side electrode 90 can be formed by a deposition method, for example. With the above procedure, a light emitting device 100 of the present embodiment can be manufactured. Then, for example, dicing is performed to separate into respective devices.

### Second Embodiment

The following describes another embodiment of the invention of the present application, i.e., a second embodiment. FIG. 14 is a schematic cross sectional view showing a structure of a light emitting device that can be manufactured by a manufacturing method of the second embodiment. With reference to FIG. 14 and FIG. 7, a light emitting device 150 that can be manufactured by the manufacturing method of the present embodiment basically has a structure similar to that of the first embodiment and exhibits an effect similar to that of the first embodiment. However, light emitting device 150 that can be manufactured by the manufacturing method of the present embodiment is different from that of the first embodiment in terms of the position at which the n side electrode is formed.

With reference to FIG. 14 and FIG. 7, in light emitting device 150 shown in FIG. 14, protrusions 20 and first semiconductor layer 30 are removed from light emitting device 100 of the first embodiment shown in FIG. 7, and n side electrode 90 is formed in contact with n type semiconductor layer 40. N side electrode 90 is disposed on the main surface of n type semiconductor layer 40 opposite to quantum well structure 50.

Light emitting device 150 is advantageous over the structure of the first embodiment in the following point: light (ultraviolet light) is avoided from being absorbed by protrusions 20 and first semiconductor layer 30.

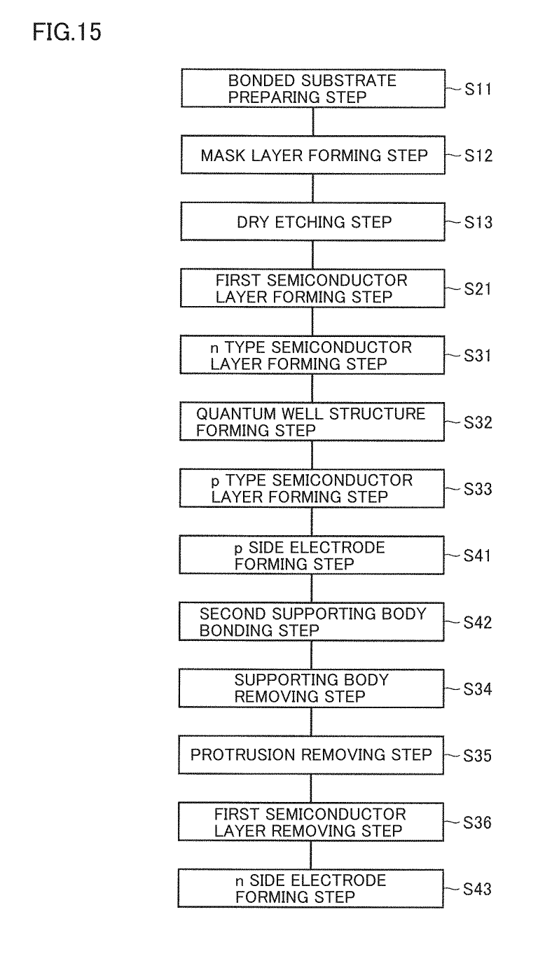

Light emitting device 150 can be manufactured by removing protrusion 20 and first semiconductor layer 30 in the method for manufacturing light emitting device 100 of the first embodiment and then forming an n side electrode. FIG. 15 is a flowchart schematically showing the method for manufacturing the light emitting device in the second embodiment. With reference to FIG. 15, the steps (S11) to (S42) are first performed in the same manner as in the first embodiment. Accordingly, the structure shown in FIG. 13 is obtained.

Next, with reference to FIG. 13, the step (S34) is performed in the same manner as in the first embodiment, thereby removing supporting body 10. Further, a protrusion removing step as a step (S35) and a first semiconductor layer removing step as a step (S36) are performed sequentially. In the step (S35), protrusions 20 are removed. In the step (S36), first semiconductor layer 30 is removed. The removal of protrusions 20 and first semiconductor layer 30 in the steps (S35) and (S36) can be performed by dry etching, for example. Accordingly, the main surface of n type semiconductor layer 40 opposite to quantum well structure 50 is exposed.

Next, an n side electrode forming step is performed as a step (S43). In this step (S43), n side electrode 90 is formed in contact with the main surface of n type semiconductor layer 40 opposite to quantum well structure 50, the main surface being exposed due to the removal of first semiconductor layer 30 in the step (S36). N side electrode 90 can be formed by a deposition method, for example. With the above procedure, light emitting device 150 can be manufactured. Then, for example, dicing is performed to separate into respective devices.

### Example 1

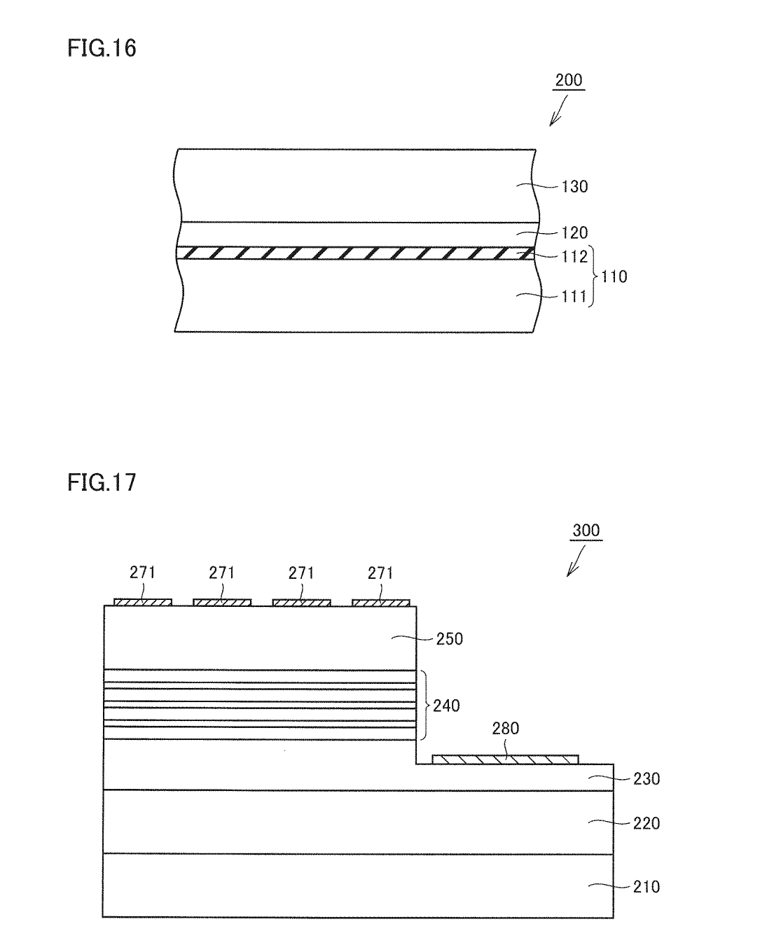

By performing the steps (S11) to (S21) in the same procedure as in the first embodiment (see FIG. 8), semiconductor layered body 2 shown in FIG. 1 was produced (Example A). Then, an experiment was conducted to check morphology of the surface (main surface opposite to supporting body 10) of first semiconductor layer 30, and identify the half widths of X-ray rocking curves of the (0002) plane and (10-12) plane of first semiconductor layer 30. For comparison, in the manufacturing method of FIG. 8, the steps (S12) and (S13) are omitted and a semiconductor layered body 200 shown in FIG. 16 was produced (Comparative Example A). Semiconductor layered body 200 includes: a supporting body 110, which is the same as supporting body 10 of the first embodiment; a group III nitride layer 120 disposed on supporting body 110 and composed of the same material as that of protrusion 20 of the first embodiment; and a first semiconductor layer 130 formed on group III nitride layer 120 and composed of the same material as that of first semiconductor layer 30 of the first embodiment. That is, semiconductor layered body 200 has a structure in which group III nitride layer 120, which is a continuous layer, is employed instead of cyclic protrusions 20 in the same structure as that of semiconductor layered body 2 of the first embodiment. This semiconductor layered body 200 was also subjected to checking of morphology and measurement of half widths in the same manner as in Example A. The morphology of the surface thereof was checked through observation using a differential interference microscope and a SEM (Scanning Electron Microscope). The half widths of the X-ray rocking curves of the (0002) plane and (10-12) plane were measured using an X-ray diffractometer. Smaller half widths mean more excellent crystallinity. The result of the experiment is shown in Table 1.

TABLE 1

| | Example A | Comparative Example A |
|---|---|---|
| Surface Morphology | Flat | Multiplicity of Cracks |
| Half Width of (0002) Plane | 342 | 910 |
| (arcsec) | | |
| Half Width of (10-12) Plane | 495 | 1076 |
| (arcsec) | | |

With reference to Table 1, improved surface morphology is observed in Example A as compared with Comparative Example A. Moreover, the half widths of the X-ray rocking curves of the (0002) plane and (10-12) plane in Example A are improved to be less than ½ of those in Comparative Example A. Thus, according to the semiconductor layered body of the present application, it is confirmed that the first semiconductor layer having excellent crystallinity is obtained and there can be provided a semiconductor layered body allowing for an improved light emitting property of the light emitting device. Since Example A is different from Comparative Example A in that group III nitride layer 120 is replaced with protrusions 20, it is considered that the improvement is attained because the stress resulting from the difference in lattice constant between each protrusion 20 and first semiconductor layer 30 is released in noncontact region 31B.

### Example 2

Light emitting device 150 shown in FIG. 14 was produced in the same procedure as that in the second embodiment (Example B). The planar shape of a chip was a square shape having sides each having a length of 1 mm. An optical output (peak) was measured when light emitting device 150 was fed with a pulse current having a frequency of 1 kHz and a duty ratio of 5% under a condition of a current value of 100 mA. For comparison, a conventional light emitting device 300 shown in FIG. 17 was produced (Comparative Example B). Then, optical output was measured in the same manner as in Example B.

With reference to FIG. 17, light emitting device 300 includes: a sapphire substrate 210; a buffer layer 220 formed on sapphire substrate 210; an n type semiconductor layer 230 formed on buffer layer 220; a quantum well structure 240 formed on n type semiconductor layer 230; and a p type semiconductor layer 250 formed on quantum well structure 240. A p side electrode 271 is formed on p type semiconductor layer 250. Moreover, a trench is formed to extend through p type semiconductor layer 250 and quantum well structure 240 and have a bottom portion in n type semiconductor layer 230. Moreover, an n side electrode 280 is formed in contact with n type semiconductor layer 230 exposed at the bottom of the trench. Buffer layer 220 is composed of AlN. N type semiconductor layer 230 and p type semiconductor layer 250 are composed of the same materials as those of n type semiconductor layer 40 and p type semiconductor layer 60 of Example B, respectively. Moreover, quantum well structure 240 is composed of the same material as that of quantum well structure 50 of Example B, and has the same structure as that of quantum well structure 50 of Example B. P side electrode 271 and n side electrode 280 are composed of the same materials as those of p side electrode 70 and n side electrode 90 of Example B, respectively. The result of the experiment is shown in Table 2.

TABLE 2

| | Example B | Comparative Example B |
|---|---|---|
| Optical Output (mW) | 1.8 | 1.5 |

With reference to Table 2, the optical output of the light emitting device of Example B is increased by 20% as compared with the light emitting device of Comparative Example B. Accordingly, it is confirmed that according to the method for manufacturing the light emitting device in the present application, a light emitting device having excellent light emitting efficiency can be manufactured. Since the light emitting device of Example B has the quantum well structure, which is formed by the epitaxial growth, on the first semiconductor layer having excellent crystallinity, it is considered that higher light emitting efficiency was obtained as compared with Comparative Example B including the quantum well structure formed on the conventional sapphire substrate. Moreover, it is considered that the light emitting efficiency in Example B was improved also due to such a fact that causes of decrease in light emitting efficiency in the light emitting device of Comparative Example B, i.e., leakage current via the wall surface of the trench and decrease of the light emission region due to the formation of the trench are avoided in Example B.

It should be noted that in the present application, the state in which the protrusions are disposed at an equal interval and the state in which the protrusions have the same shape do not mean a geometrically completely equal interval and geometrically completely the same shape, but include errors inevitable in manufacturing. In other words, the state in which the protrusions are disposed at an equal interval and the state in which the protrusions have the same shape include a case where the inevitable errors are included as a result of manufacturing although the equal intervals and the same shape are intended to be attained.

It should be understood that the embodiments and examples disclosed herein are illustrative and non-restrictive in any respect. The scope of the present invention is defined by the terms of the claims, rather than the embodiments described above, and is intended to include any modifications within the scope and meaning equivalent to the terms of the claims.

### REFERENCE SIGNS LIST

1: base layered body; 2: semiconductor layered body; 3: quantum well structure equipped semiconductor layered body; 10: supporting body; 10A: supporting main surface; 11: base body; 12: dielectric film; 20: protrusion; 21: first main surface; 22: second main surface; 23: end surface; 25: corner portion; 28: group III nitride layer; 29: groove portion; 30: first semiconductor layer; 31: first main surface; 31A: contact region; 31B: noncontact region; 32: second main surface; 40: n type semiconductor layer; 40A: first main surface; 50: quantum well structure; 50A: main surface; 51: quantum well layer; 52: barrier layer; 60: p type semiconductor layer; 61: main surface; 70: p side electrode; 71: main surface; 81: solder layer; 82: second supporting body; 90: n side electrode; 91: mask layer; 92: opening; 99: reference plane; 100: light emitting device; 150: light emitting device.

1: A semiconductor layered body comprising:
a plurality of protrusions having first main surfaces along a reference plane and protruding from the reference plane; and
a first semiconductor layer disposed at a side of the plurality of protrusions opposite to the first main surfaces so as to connect the plurality of protrusions to one another,
each of the protrusions being composed of a group III nitride that has a dislocation density of less than or equal to 1×10⁸ cm⁻³, that is expressed by a composition formula of AlₓGa₁₋ₓN, and that satisfies 0≤x<1,
the first semiconductor layer being composed of a group III nitride that has a dislocation density of less than or equal to 1×10⁹ cm⁻³, that is expressed by a composition formula of Al_{y}Ga_{1-y}N, and that satisfies 0<y≤1.

2: The semiconductor layered body according to claim 1, further comprising a supporting body having a supporting main surface overlapping with the reference plane, wherein the plurality of protrusions are formed on the supporting main surface.

3: The semiconductor layered body according to claim 1, wherein the first semiconductor layer has a dislocation density of less than or equal to 1×10⁸ cm⁻³.

4: The semiconductor layered body according to claim 1, wherein when viewed in a plan view, an area ratio of a region overlapping with the protrusions in the first semiconductor layer is more than or equal to 30% and less than or equal to 90%.

5: The semiconductor layered body according to claim 1, wherein in the first semiconductor layer, a half width of an X-ray rocking curve of a (0002) plane, which is a symmetric plane, is less than or equal to 800 arcsec and a half width of an X-ray rocking curve of a (10-12) plane, which is an asymmetric plane, is less than or equal to 1500 arcsec.

6: The semiconductor layered body according to claim 1, further comprising a second semiconductor layer disposed on a main surface of the first semiconductor layer opposite to the protrusions, the second semiconductor layer including a quantum well structure.

7: A light emitting device comprising:
the semiconductor layered body recited in claim 1; and
an electrode formed on the semiconductor layered body.

8: The light emitting device according to claim 7, wherein the light emitting device is configured to emit ultraviolet light.

9: A method for manufacturing a light emitting device, the method comprising:
preparing a semiconductor layered body; and
forming an electrode on the semiconductor layered body,
the preparing of the semiconductor layered body including
forming a plurality of protrusions having first main surfaces along a reference plane and protruding from the reference plane, and
forming a first semiconductor layer at a side of the plurality of protrusions opposite to the first main surfaces so as to connect the plurality of protrusions to one another,
each of the protrusions being composed of a group III nitride that has a dislocation density of less than or equal to 1×10⁸ cm⁻³, that is expressed by a composition formula of AlₓGa₁₋ₓN, and that satisfies 0≤x<1,
the first semiconductor layer being composed of a group III nitride that has a dislocation density of less than or equal to 1×10⁹ cm⁻³, that is expressed by a composition formula of Al_{y}Ga_{1-y}N, and that satisfies 0<y≤1.

10: The method for manufacturing the light emitting device according to claim 9, wherein in the forming of the protrusions, the plurality of protrusions are formed on a supporting main surface of a supporting body, the supporting main surface overlapping with the reference plane.

11: The method for manufacturing the light emitting device according to claim 9, wherein the preparing of the semiconductor layered body further includes forming a second semiconductor layer on a main surface of the first semiconductor layer opposite to the protrusions, the second semiconductor layer including a quantum well structure.

12: The method for manufacturing the light emitting device according to claim 11, wherein the preparing of the semiconductor layered body further includes removing the protrusions and the first semiconductor layer after the forming of the second semiconductor layer.
